(19) United States
(12) Patent Application Publication
(10) Pub. No.: US 2008/0242067 A1
(43) Pub. Date: Oct. 2, 2008

(54) SEMICONDUCTOR SUBSTRATE AND METHOD OF MANUFACTURE THEREOF

(76) Inventors: Masanobu OGINO, Yokosuka (JP); Yoshikatsu Suto, Nishiokitama-gun (JP); Yoshiro Baba, Yokohama (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/111,512

(22) Filed: Apr. 29, 2008

Related U.S. Application Data
(62) Division of application No. 10/713,054, filed on Nov. 17, 2003.

(30) Foreign Application Priority Data
Nov. 18, 2002 (JP) 2002-333682
Apr. 4, 2003 (JP) 2003-101614

(51) Int. Cl. H01L 21/22

(52) U.S. Cl. 438/542; 257/E21.135

(57) ABSTRACT

A semiconductor substrate is disclosed, which comprises a lightly doped substrate that contains impurities at a low concentration, a heavily doped diffusion layer which is formed over a top of the lightly doped substrate and is higher in impurity concentration than the lightly doped substrate, and an epitaxial layer which is formed over a top of the heavily doped diffusion layer and contains impurities at a lower concentration than the heavily doped diffusion layer.

### CROSS-REFERENCE TO RELATED APPLICATIONS

This application is based upon and claims the benefit of priority from the prior Japanese Patent Applications No. 2002-333682, filed Nov. 18, 2002; and No. 2003-101614, filed Apr. 4, 2003, the entire contents of both of which are incorporated herein by reference.

### BACKGROUND OF THE INVENTION

1. Field of the Invention

The present invention relates to a semiconductor substrate and a method of manufacture thereof. More specifically, the present invention relates to a semiconductor substrate used in a semiconductor device and a method of manufacture thereof.

2. Description of the Related Art

Conventionally, most conventional semiconductor substrates for semiconductor devices, which are generally referred to as bipolar transistors or power MOSFETs, are ones in which a lightly doped silicon epitaxial layer is formed on the top of a substrate that is heavily doped with impurities, such as arsenic, antimony, phosphorous, or boron (generally arsenic) and has its surface mirror finished.

To manufacture such a heavily doped substrate, it is required to dope a substrate with a large amount of impurities at the time of single crystal growth by the Czochralski method. However, introducing impurities at the highest possible concentration within the solid solubility limit in manufacturing the heavily doped substrate makes the growth of single crystal difficult, resulting in poor yields. Additionally, a phenomenon called segregation makes it difficult to introduce impurities uniformly in the direction of crystal length in a lot, that is, to grow crystal uniform in resistivity. Thus, the manufacture of a heavily doped substrate by introducing a large amount of impurities into the substrate at the single crystal growth time results in an increase in the cost of manufacture.

With the heavily doped substrate thus obtained, the heavily doped semiconductor substrate layer on the back side of the substrate remains uncovered. At the time of forming an epitaxial layer on the top of the heavily doped substrate, therefore, the impurities within the substrate will diffuse from the back side to outside and the diffusing impurities will then get into the surface of the epitaxial layer on the top of the substrate. In order to prevent the diffusion of impurities from the back side of the substrate to outside at the time of epitaxial layer formation, it is required to form a passivating film (oxide film or polysilicon film) on the back of the substrate, which further increases the cost of manufacture.

Conventionally, there is a method of manufacturing a semiconductor substrate for a thyristor, which involves forming an impurity diffusion layer on the surface of a semiconductor substrate, then mirror polishing mechanically and chemically the surface of the impurity diffusion layer to remove the surface portion of a given thickness and forming a heavily doped epitaxial layer on the mirror finished impurity diffusion layer (see Japanese Patent application KOKAI Publication No. 59-35421).

With this conventional technique, in order to form the impurity diffused layer on the substrate surface, oxide films are formed on both sides of the substrate, phosphorus is implanted through the oxide films into a wafer at 140 KeV and at a dose of 7×10¹⁴ cm⁻², and the resulting wafer is heated for about 50 hours at 1260° C. in a mixed gas of nitrogen and oxygen to diffuse phosphorus into the wafer. After that, the surface of the wafer is mirror polished mechanically and chemically using silicic acid powder to remove the phosphorus diffused layer by 5 μm in thickness and an N-type monocrystalline epitaxial layer of 0.1 Ωcm in specific resistance is formed on the mirror polished wafer surface by means of epitaxial growth techniques.

This conventional technique is intended to form a defectless epitaxial layer in the manufacture of a semiconductor substrate for a thyristor. Specifically, the technique involves forming a diffusion layer on a substrate, then polishing the surface of the diffusion layer mechanically and chemically and forming an epitaxial layer on the polished diffusion layer, whereby a defectless epitaxial layer is formed.

Furthermore, in order to form a heavily doped diffusion layer on a substrate, the conventional technique involves ion implanting dopants into the substrate at a dose of 7×10¹⁴ cm⁻² and then diffusing the implanted dopants through high-temperature heat treatment. After that, an epitaxial layer of 0.1 Ωcm in specific resistance is formed on the substrate. With this method of formation, it is expected that the impurity concentration of the substrate (lower layer) and the impurity concentration of the epitaxial layer (upper layer) are substantially equal to each other. In order to make the impurity concentration of the diffusion layer higher, ion implantation is simply performed for a longer time at a higher dose; however, this will result in lower productivity and consequently in higher cost of manufacture.

### BRIEF SUMMARY OF THE INVENTION

According to an aspect of the present invention, there is provided a semiconductor substrate comprising:

a lightly doped substrate that contains impurities at a low concentration;

a heavily doped diffusion layer which is formed over a top of the lightly doped substrate and is higher in impurity concentration than the lightly doped substrate; and

an epitaxial layer which is formed over a top of the heavily doped diffusion layer and contains impurities at a lower concentration than the heavily doped diffusion layer.

According to another aspect of the present invention, there is provided a method of manufacturing a semiconductor substrate comprising:

forming, on a surface of a lightly doped substrate that contains impurities at a low concentration, a heavily doped diffusion layer which is higher in impurity concentration than the lightly doped substrate;

mirror finishing a surface of the heavily doped diffusion layer; and

forming an epitaxial layer on the surface mirror finished of the heavily doped diffusion layer, the epitaxial layer containing impurities at a lower concentration than the heavily doped diffusion layer.

According to a further aspect of the present invention, there is provided a method of manufacturing a semiconductor substrate comprising:

mirror finishing a surface of a lightly doped substrate that contains impurities at a low concentration;

forming, on the surface mirror finished of the lightly doped substrate, a heavily doped diffusion layer which is higher in impurity concentration than the lightly doped substrate; and

forming an epitaxial layer on a surface of the heavily doped diffusion layer, the epitaxial layer containing impurities at a lower concentration than the heavily doped diffusion layer.

According to a still further aspect of the present invention, there is provided a method of manufacturing a semiconductor substrate comprising:

forming, on top and back of a lightly doped substrate that contains impurities at a low concentration, heavily doped diffusion layers which are higher in impurity concentration than the lightly doped substrate;

removing the heavily doped diffusion layer which is formed on one of the top and back of the lightly doped substrate;

mirror finishing a surface of the heavily doped diffusion layer which is formed on the other of the top and back of the lightly doped substrate; and

forming an epitaxial layer on the surface mirror finished of the heavily doped diffusion layer, the epitaxial layer containing impurities at a lower concentration than the heavily doped diffusion layer.

According to a yet further aspect of the present invention, there is provided a method of manufacturing a semiconductor substrate comprising:

forming, on the top and the back of a lightly doped substrate that contains impurities at a low concentration, heavily doped diffusion layers which are higher in impurity concentration than the lightly doped substrate;

dividing the substrate into divided substrates by cutting it along a surface thereof at a center in a thickness direction;

planarizing a cut surface of each of the divided substrates;

mirror finishing a surface of the heavily doped diffusion layer which is formed on each of the divided substrates; and

forming an epitaxial layer on the surface mirror finished of the heavily doped diffusion layer on each of the divided substrates, the epitaxial layer containing impurities at a lower concentration than the heavily doped diffusion layers.

According to a further aspect of the present invention, there is provided a semiconductor substrate comprising:

a semiconductor element;

a heavily doped diffusion layer which is formed over a top of a lightly doped substrate and is higher in impurity concentration than the lightly doped substrate, the lightly doped substrate being removed at a final stage of a process of forming the semiconductor element; and

an epitaxial layer which is formed over a top of the heavily doped diffusion layer and contains impurities at a lower concentration than the heavily doped diffusion layer, the semiconductor element being formed in the epitaxial layer.

### BRIEF DESCRIPTION OF THE SEVERAL VIEWS OF THE DRAWING

FIG. 1 is a sectional view of a semiconductor substrate;

FIG. 2 is a sectional view of a semiconductor substrate according to an embodiment of the present invention in which a heavily doped diffusion layer and an epitaxial layer are formed on the semiconductor substrate of FIG. 1;

FIG. 3 is a sectional view of a semiconductor substrate;

FIG. 4 is a sectional view of a semiconductor substrate according to another embodiment of the present invention in which a heavily doped diffusion layer and an epitaxial layer are formed on the semiconductor substrate of FIG. 3;

FIG. 5 is a sectional view of a semiconductor substrate, for explaining a step of a manufacturing method according to an embodiment of the present invention;

FIG. 6 is a sectional view of the semiconductor substrate, for explaining a step following the step of FIG. 5 of the manufacturing method according to the embodiment of the present invention;

FIG. 7 is a sectional view of the semiconductor substrate, for explaining a step following the step of FIG. 6 of the manufacturing method according to the embodiment of the present invention;

FIG. 8 is a sectional view of the semiconductor substrate, for explaining a step following the step of FIG. 7 of the manufacturing method according to the embodiment of the present invention;

FIG. 9 is a sectional view of the semiconductor substrate, for explaining a step following the step of FIG. 8 of the manufacturing method according to the embodiment of the present invention;

FIG. 10 is a sectional view of the semiconductor substrate, for explaining a step following the step of FIG. 9 of the manufacturing method according to the embodiment of the present invention;

FIG. 11 is a sectional view of a semiconductor substrate, for explaining a step of a manufacturing method according to another embodiment of the present invention;

FIG. 12 is a sectional view of the semiconductor substrate, for explaining a step following the step of FIG. 11 of the manufacturing method according to the embodiment of the present invention;

FIG. 13 is a sectional view of the semiconductor substrate, for explaining a step following the step of FIG. 12 of the manufacturing method according to the embodiment of the present invention;

FIG. 14 is a sectional view of the semiconductor substrate, for explaining a step following the step of FIG. 13 of the manufacturing method according to the embodiment of the present invention;

FIG. 15 is a sectional view of the semiconductor substrate, for explaining a step following the step of FIG. 14 of the manufacturing method according to the embodiment of the present invention;

FIG. 16 is a sectional view of the semiconductor substrate, for explaining a step following the step of FIG. 15 of the manufacturing method according to the embodiment of the present invention;

FIG. 17 is a sectional view of a semiconductor substrate, for explaining a step of a manufacturing method according to a further embodiment of the present invention;

FIG. 18 is a sectional view of the semiconductor substrate, for explaining a step following the step of FIG. 17 of the manufacturing method according to the embodiment of the present invention;

FIG. 19 is a sectional view of the semiconductor substrate, for explaining a step following the step of FIG. 18 of the manufacturing method according to the embodiment of the present invention;

FIG. 20 is a sectional view of the semiconductor substrate, for explaining a step following the step of FIG. 19 of the manufacturing method according to the embodiment of the present invention;

FIG. 21 is a sectional view of the semiconductor substrate, for explaining a step following the step of FIG. 20 of the manufacturing method according to the embodiment of the present invention;

FIG. 22 is a sectional view of the semiconductor substrate, for explaining a step following the step of FIG. 21 of the manufacturing method according to the embodiment of the present invention;

FIG. 23 is a sectional view of a semiconductor substrate, for explaining a step of a manufacturing method according to a still further embodiment of the present invention;

FIG. 24 is a sectional view of the semicontductor substrate, for explaining a step following the step of FIG. 23 of the manufacturing method according to the embodiment of the present invention;

FIG. 25 is a sectional view of the semiconductor substrate, for explaining a step following the step of FIG. 24 of the manufacturing method according to the embodiment of the present invention;

FIG. 26 is a sectional view of the semiconductor substrate, for explaining a step following the step of FIG. 25 of the manufacturing method according to the embodiment of the present invention;

FIG. 27 is a sectional view of the semiconductor substrate, for explaining a step following the step of FIG. 26 of the manufacturing method according to the embodiment of the present invention;

FIG. 28 is a sectional view of the semiconductor substrate, for explaining a step following the step of FIG. 27 of the manufacturing method according to the embodiment of the present invention;

FIG. 29 is a sectional view of the semiconductor substrate, for explaining a step following the step of FIG. 28 of the manufacturing method according to the embodiment of the present invention;

FIG. 30 is a cross sectional view of a semiconductor device, for explaining a step of a manufacturing method of the semiconductor device, using the substrate shown in FIG. 10;

FIG. 31 is a sectional view of the semiconductor device, for explaining a step following the step of FIG. 30 of the manufacturing method;

FIG. 32 is a cross sectional view of a semiconductor device, for explaining a step of a manufacturing method of the semiconductor device, using the substrate shown in FIG. 16;

FIG. 33 is a sectional view of the semiconductor device, for explaining a step following the step of FIG. 32 of the manufacturing method;

FIG. 34 is a cross sectional view of a semiconductor device, for explaining a step of a manufacturing method of the semiconductor device, using the substrate shown in FIG. 22;

FIG. 35 is a sectional view of the semiconductor device, for explaining a step following the step of FIG. 34 of the manufacturing method;

FIG. 36 is a cross sectional view of a semiconductor device, for explaining a step of a manufacturing method of the semiconductor device, using the substrate shown in FIG. 29; and

FIG. 37 is a sectional view of the semiconductor device, for explaining a step following the step of FIG. 36 of the manufacturing method.

### DETAILED DESCRIPTION OF THE INVENTION

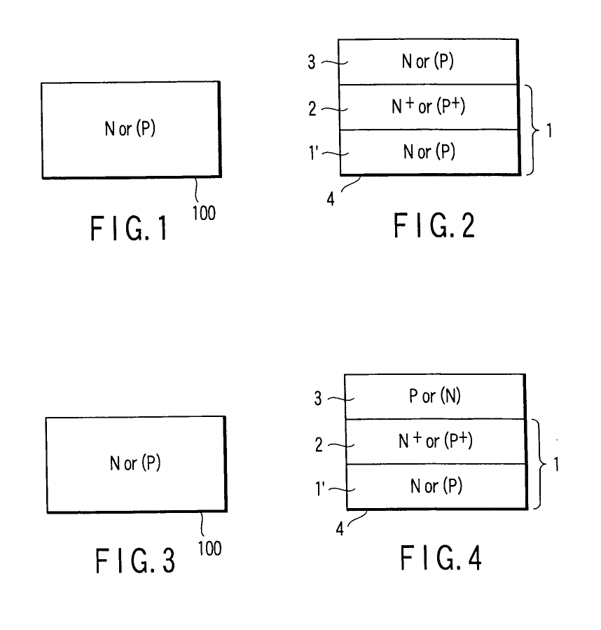

FIGS. 1 and 3 are sectional views of a semiconductor substrate. This semiconductor substrate is a lightly doped semiconductor substrate (semiconductor wafer) which contains impurities at a low concentration and is formed by slicing a monocrystalline ingot. This substrate is one prior to formation of layers such as an impurity diffusion layer, an epitaxial layer, etc.

The lightly doped substrate 100 is usually doped with impurities of N- or P-type conductivity at the time of single-crystal growth through the Czochralski method. In FIGS. 1 and 3, N and P indicate the conductivity types of semiconductors. This is the same with the other drawings. The symbol “+” indicates that the impurity concentration is high. The impurities of N-type conductivity include phosphorus, antimony, and arsenic. The impurities of P-type conductivity include boron.

Impurities of the same conductivity type as those in the lightly doped substrate 100 are diffused into the substrate at a high concentration by means of diffusing techniques, so that a heavily doped diffusion layer formed substrate 1 is produced in which a heavily doped diffusion layer 2 is formed in the upper portion of the substrate 100 as shown in FIGS. 2 and 4 which correspond to FIGS. 1 and 3, respectively. The symbol “+” in FIGS. 2 and 4 indicates that the impurity concentration is high. This is the same with the other drawings. It is desirable that the thickness of the heavily doped diffusion layer 2 be smaller than that of the lightly doped substrate 100. It is desirable that, at the time of diffusion, a non-diffusion layer 1′ be left in the substrate having the heavily doped diffusion layer 2 formed thereon.

Next, an epitaxial layer 3 is formed on the heavily doped diffusion layer 2 of the substrate 1, which contains impurities at a lower concentration than the heavily doped diffusion layer 2.

The epitaxial layer 3 may be of the same conductivity type as the lightly doped substrate and the heavily doped diffusion layer as shown in FIG. 2 or may be of the opposite conductivity type to the lightly doped substrate and the heavily doped diffusion layer as shown in FIG. 4. That is, as shown in FIGS. 1 and 2, when the lightly doped substrate and the heavily doped diffusion layer are of N-type conductivity, the epitaxial layer may also be of N-type conductivity and, when the lightly doped substrate and the heavily doped diffusion layer are of P-type conductivity, the epitaxial layer may also be of P-type conductivity. Alternately, as shown in FIGS. 3 and 4, when the lightly doped substrate and the heavily doped layer diffusion are of N-type conductivity, the epitaxial layer is allowed to be of P-type conductivity and, when the lightly doped substrate and the heavily doped diffusion layer are of P-type conductivity, the epitaxial layer is allowed to be of N-type conductivity. Power devices, such as IGBTs (Insulated Gate Bipolar Transistors), have the opposite conductivity type structure as shown in FIG. 4.

The impurity concentration of the lightly doped substrate 100 can be set so low that such outward diffusion of impurities contained in the substrate as affects the resistivity of the epitaxial layer 3 will not occur. For this reason, the substrate can be fabricated at a low cost in comparison with conventional heavily doped substrates. It is advisable that the impurity concentration of the lightly doped substrate 100 be less than 10 times that of the epitaxial layer 3.

Since the heavily doped diffusion layer 2 is formed by means of diffusion techniques, a uniform resistivity distribution can be obtained in a lot without being affected by segregation occurred at the crystal growth time in the formation of conventional heavily doped substrates. In addition, since the heavily doped diffusion layer 2 is formed so as not to reach the back 4 of the substrate 1, the impurities will not travel from the back 4 to the top (epitaxial layer surface) of the substrate 1 at the time of epitaxial growth or in the semiconductor device formation process. Thus, an excess step of forming a passivation film on the back of the substrate can be simplified.

If the non-doped layer 1′ of the substrate 1 were left after the formation of the semiconductor device, device characteristics would be degraded. In general, the layer 1′ is removed by grinding at the final stage in the device manufacturing process; therefore, there is no problem. The substrate after the layer 1′ has been removed, if it is too small in thickness, is susceptible to cracking in the subsequent steps and is therefore required to have a thickness of 50 μm or more. It is desirable that the sum of thickness of the epitaxial layer 3 and the heavily doped diffusion layer 2 be 50 μm or more.

In a method of manufacturing a semiconductor substrate in accordance with another embodiment of the present invention, a lightly doped substrate that contains impurities at a low doping level is formed on top or underneath (top in this example) with a diffusion layer which is more heavily doped with impurities than that substrate.

To form the heavily doped diffusion layer, a conventional technique is applied, which, for example, involves placing the semiconductor substrate in an electric furnace, subjecting the semiconductor substrate to heat treatment in a mixed gas of oxygen, nitrogen, and POCl₃, and further carrying out heat treatment at a higher temperature. Next, the top of the substrate formed with the heavily doped diffusion layer is mirror finished. The mirror finishing process described herein includes at least a chemical mechanical polishing process which allows the finished surface of the substrate to become a mirror. If processing processes through the chemical mechanical polishing process are necessary, they should be included. The processing processes include grinding using a diamond grindstone and etching by an acid chemical (for example, a solution of nitric acid, acetic acid, and hydrofluoric acid). In recent years, the plasma etching technique has been extensively established. If this technique is used as the final process, it should also be included. Next, an epitaxial layer that contains impurities at a lower concentration than the heavily doped diffusion layer is formed on the mirror finished surface. The formation of this epitaxial layer is carried out by means of conventional techniques using, for example, SiHCl₃ as a silicon source, H₂ as a carrier gas, and PH₃ as a dopant gas. In this method of manufacture, the mirror finishing may be performed prior to formation of the heavily doped diffusion layer. Further, it is desirable that the other substrate surface which is not formed with a heavily doped diffusion layer (the back of the substrate in this example) have been protected by an oxide film or the like before the heavily doped diffusion layer is formed. The formation of thispassivation film can be achieved by, assuming that the passivation film is an oxide film, forming oxide films on both the top and the underneath of the substrate prior to formation of the heavily doped diffusion layer and then etching away the oxide film on the top of the substrate (the surface on which the epitaxial layer is to be formed) by means of spin etching.

In a method of manufacturing a semiconductor substrate in accordance with still another embodiment of the present invention, a lightly doped substrate 100 that contains impurities at a low concentration is formed on top and underneath with diffusion layers each of which is more heavily doped with impurities than that substrate. The heavily doped diffusion layers can be formed by the aforementioned conventional technique. Next, the heavily doped diffusion layer on one of the substrate surfaces (the underneath in this example) is removed to expose the non-diffusion layer. It is desirable that the removal of the heavily doped diffusion layer in this case be carried out by single-side grinding using a diamond grindstone, single-side etching based on plasma or spin etching, or single-side polishing. In a configuration to leave the heavily doped diffusion layer, both-side grinding, both-side etching and both-side polishing may be performed in combination. Next, the top of the substrate on which the heavily doped diffusion layer is left is mirror-finished. At this point, depending on the conditions of the surface (top of the substrate) of the heavily doped diffusion layer, grinding using a diamond grindstone, plasma or spin etching and polishing may be performed in combination. In leaving the non-diffused layer that forms the back side of the substrate, both-side grinding, both-side etching and both-side polishing may be performed in combination. After the mirror finishing, an epitaxial layer that contains impurities at a low concentration is formed on the mirror-finished heavily-doped diffusion layer by means of the aforementioned conventional techniques.

In a method of manufacturing a semiconductor substrate in accordance with still another embodiment of the present invention, a lightly doped substrate that contains impurities at a low concentration is formed on top and underneath with diffusion layers each of which is more heavily doped with impurities than that substrate. The heavily doped diffusion layers can be formed by the aforementioned conventional technique. After that, the substrate is divided into two by slicing it along its surface at the center in the direction of its thickness by means of an inner diameter saw or a wire saw. Thereby, a non-diffusion layer is exposed on each divided surface. Next, the divided surface (non-diffusion layer exposed surface) of each divided substrate is planarized. This planarization is preferably carried out by means of single-side grinding using a diamond grindstone, single-side etching based on plasma or spin etching, or single-side polishing. At this point, in a configuration to leave one of the heavily doped diffusion layers, both-side grinding, both-side etching and both-side polishing may be carried out in combination. Next, the surface of the heavily doped diffusion layer (the substrate surface on the heavily doped diffusion layer side) is mirror finished. At this point, depending on the surface conditions of the heavily doped diffusion layer, grinding using a diamond grindstone, plasma or spin etching and polishing may be performed in combination. In a configuration to leave the non-diffusion layer, both-side grinding, both-side etching and both-side polishing may be performed in combination. After the mirror finishing, the mirror-finished heavily doped diffusion layer is formed on top with an epitaxial layer that is more lightly doped with impurities than that diffusion layer by means of the aforementioned conventional techniques.

In the aforementioned manufacturing methods, the impurities to be diffused should preferably be high in diffusion rate. It is recommended that the N-type impurity be phosphorus and the P-type impurity be boron. With the P-type impurity, aluminum is greater in diffusion coefficient than boron. For silicon semiconductor, however, the solid solubility limit of aluminum is at least one order of magnitude smaller than with boron. Therefore, boron is desirable as the P-type impurity to be diffused into silicon semiconductors. The substrate is not limited to silicon and may be some other semiconductor material such as germanium.

### EXAMPLE 1

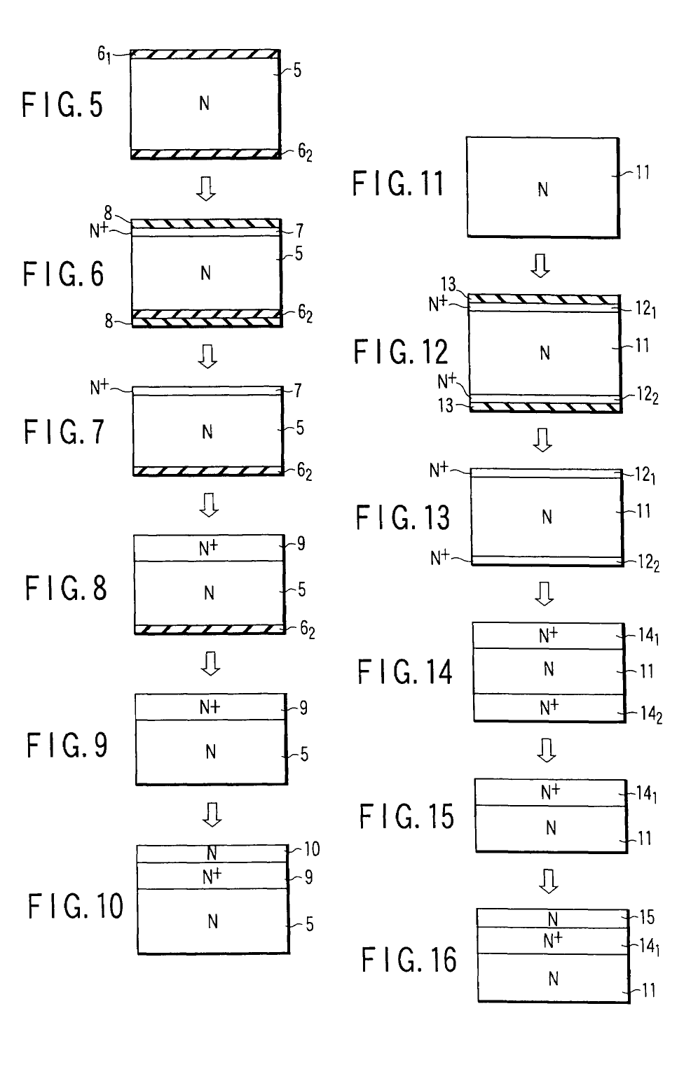

As shown in FIG. 5, an N-type semiconductor substrate 5 was prepared which was 150 mm in diameter, 10 Ωcm in specific resistance, and 625 μm in thickness and had its top mirror polished. The semiconductor substrate 5 was heat treated to form oxide films 61 and 62 on its top and back.

The oxide film 61 on the top (i.e. polished side) of the N-type semiconductor substrate 5 was next removed. The substrate 5 was then inserted in an electric furnace and held at 1200° C. Then, oxygen, nitrogen and POCl₃ gases were introduced into the furnace. Heat treatment was carried out for 180 minutes, so that a deposition diffusion layer 7 in which impurities were diffused at a high concentration was formed on the top of the semiconductor substrate 5 (FIG. 6).

After that, phosphorus-doped glass layers 8 attached to the top and back of the substrate in the heat treatment were removed by etching with an acid (FIG. 7). The sheet resistance of the deposition diffusion layer 7 at this time is 0.3 Ω/□. The semiconductor substrate was subjected to heat treatment for 300 hours at 1290° C. in an argon atmosphere containing a trace quantity of oxygen to diffuse impurities in the deposition diffusion layer 7 deeper into the substrate. As the result, a heavily doped diffusion layer 9 was formed (FIG. 8). The measurement of the thickness of the heavily doped diffusion layer 9 was 220 μm.

After that, the oxide film 6₂ on the back of the semiconductor substrate 5 was removed (FIG. 9). After that, an N-type silicon epitaxial layer 10 having a thickness of 10 μm and a specific resistance of 10 Ωcm was formed on the top, i.e. the heavily doped diffusion layer 9 side of the semiconductor substrate 5 (FIG. 10). For the epitaxial growth at this point, use was made of SiHCl₃ as a silicon source, H₂ as a carrier gas, and PH₃ as a dopant gas and the growth temperature was 1150° C. The epitaxial growth rate was, on average, 1.5 μm per minute. In the heavily doped diffusion layer 9, the thickness of a region of less than 2 mΩcm in specific resistance was about 70 μm.

### EXAMPLE 2

As shown in FIG. 11, an N-type semiconductor substrate 11 was prepared which was 150 mm in diameter, 10 Ωcm in specific resistance, and 900 μm in thickness and had its top and back chemically etched.

The N-type semiconductor substrate 11 was then inserted in an electric furnace and held at 1200° C. and then oxygen, nitrogen and POCl₃ gases were introduced into the furnace. Heat treatment was carried out for 180 minutes, so that deposition diffusion layers 12₁ and 12₂ were formed on the top and back of the semiconductor substrate 11 (FIG. 12).

After that, phosphorus-doped glass layers 13 attached to the top and back of the substrate in the heat treatment were removed by etching with an acid (FIG. 13). The sheet resistance of the deposition diffusion layers 12₁ and 12₂ at this time is 0.3 Ω/□. The semiconductor substrate was subjected to heat treatment for 300 hours at 1290° C. in an argon atmosphere to diffuse impurities in the deposition diffusion layers 12₁ and 12₂ deeper into the substrate. As the result, a heavily doped diffusion layers 14₁ and 14₂ were formed (FIG. 14). The measurement of the thickness of the heavily doped diffusion layers 14₁ and 14₂ was 223 μm.

After that, the back (the heavily doped diffusion layer 14₂ side) and the top (the heavily doped diffusion layer 14₁ side) as the device formed surface of the semiconductor substrate were scraped away by 300 μm and 10 μm in thickness, respectively, using a grindstone electro-deposited with diamond. To remove damaged layers on the top and back due to the scraping, each side of the substrate was removed by 5 μm through chemical etching. After that, the surface of the heavily doped diffusion layer 14₁ was mirror polished (FIG. 15).

After that, an N-type silicon epitaxial layer 15 having a thickness of 10 μm and a specific resistance of 10 Ωcm was formed on the mirror polished surface (FIG. 16). For the epitaxial growth at this point, use was made of SiHCl₃ as a silicon source, H₂ as a carrier gas, and PH₃ as a dopant gas and the growth temperature was 1150° C. The epitaxial growth rate was, on average, 1.5 μm per minute. In the heavily doped diffusion layer 14₁, the thickness of a region of less than 2 mΩcm in specific resistance was about 50 μm.

### EXAMPLE 3

As shown in FIG. 17, a P-type semiconductor substrate 16 was prepared which was 150 mm in diameter, 15 Ωcm in specific resistance, and 900 μm in thickness and had its top and back chemically etched.

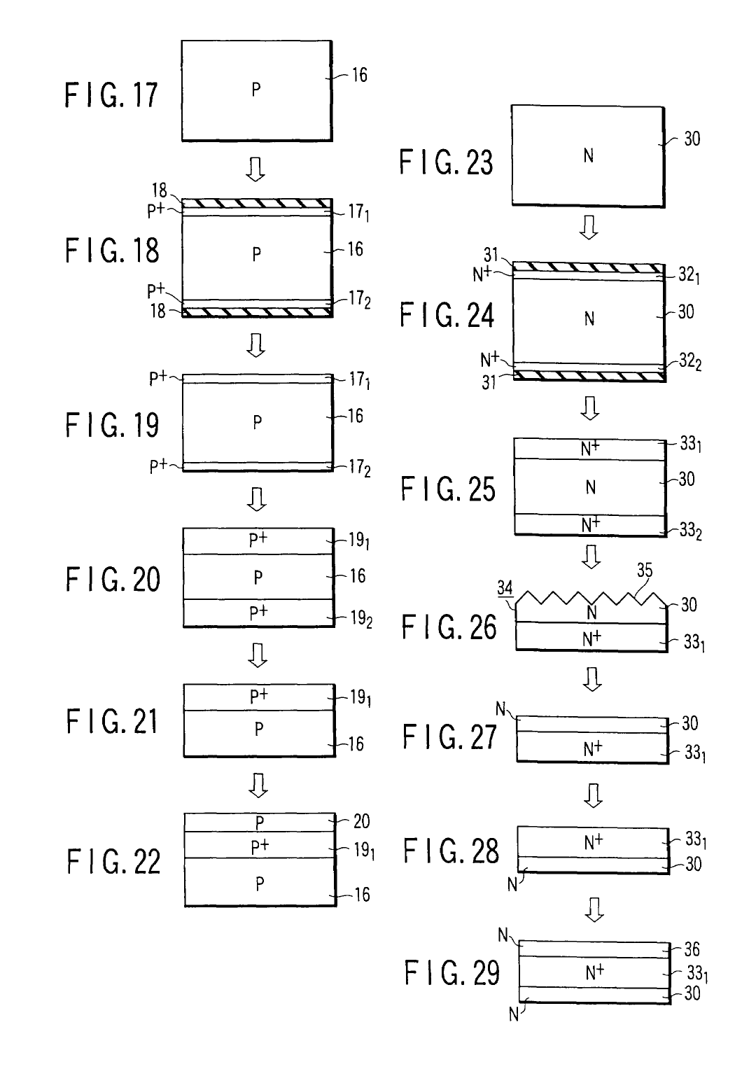

B₂O₃ powder was applied to the top and back of the P-type semiconductor substrate 16. The substrate was then inserted in an electric furnace and held at 1280° C. and then oxygen gas was introduced into the furnace. Heat treatment was carried out for 240 minutes, so that deposition diffusion layers 17₁ and 17₂ were formed on the top and back of the semiconductor substrate 16 (FIG. 18).

After that, boron-doped glass layers 18 attached to the top and back of the substrate in the heat treatment were removed with hydrofluoric acid (FIG. 19).

The semiconductor substrate was subjected to heat treatment for 180 hours at 1290° C. in an argon atmosphere to diffuse impurities in the deposition diffusion layers 17₁ and 17₂ deeper into the substrate. As the result, a heavily doped diffusion layers 19₁ and 19₂ were formed (FIG. 20). The measurement of the thickness of the heavily doped diffusion layer 19₁ was 230 μm.

After that, the back (the heavily doped diffusion layer 19₂ side) and the top (the heavily doped diffusion layer 19₁ side) as the device formed surface of the semiconductor substrate were scraped away by 300 μm and 10 μm in thickness, respectively, using a grindstone electro-deposited with diamond. To remove damaged layers on the top and back due to the scraping, each side of the substrate was removed by 5 μm through chemical etching. After that, the surface of the heavily doped diffusion layer 19₁ was mirror polished (FIG. 21).

After that, a P-type silicon epitaxial layer 20 having a thickness of 10 μm and a specific resistance of 10 Ωcm was formed on the mirror polished surface (FIG. 22). For the epitaxial growth at this point, use was made of SiHCl₃ as a silicon source, H₂ as a carrier gas, and B₂H₆ as a dopant gas and the growth temperature was 1150° C. The epitaxial growth rate was, on average, 1.5 μm per minute. In the heavily doped diffusion layer 19₁, the thickness of a region of less than 2 mΩcm in specific resistance was about 50 μm.

### EXAMPLE 4

As shown in FIG. 23, an N-type semiconductor substrate 30 was prepared which was 150 mm in diameter, 10 Ωcm in specific resistance, and 1200 μm in thickness and had its top and back lapping processed.

The substrate 30 was then placed in an electric furnace held at 650° C. The temperature of the furnace was raised to 1200° C. and then oxygen, nitrogen and POCl₃ gases were introduced into the furnace. Heat treatment was carried out for 180 minutes, so that deposition diffusion layers 32₁ and 32₂ were formed on the top and back of the semiconductor substrate 30 (FIG. 24). After that, phosphorus-doped glass layers 31 attached to the top and back of the substrate in the heat treatment were removed by etching with an acid. The sheet resistance of the deposition diffusion layers 32₁ and 32₂ at this time is 0.3 Ω/□.

The semiconductor substrate was subjected to heat treatment for 300 hours at 1290° C. in an argon atmosphere containing a trace quantity of oxygen to diffuse impurities in the deposition diffusion layers 32₁ and 32₂ deeper into the substrate. As the result, heavily doped diffusion layers 33₁ and 33₂ were formed (FIG. 25). The measurement of the thickness of the heavily doped diffusion layers 33₁ and 33₂ was 220 μm.

After that, the semiconductor substrate was divided into two by slicing it along the surface at the center in the direction of thickness using an inner diameter saw not shown (FIG. 26).

Next, irregularities 35 of the top (the dividing surface) of each of the divided substrates 34 were removed by scrapping them using a grindstone electro-deposited with diamond (FIG. 27). After that, to remove damaged layers on the top due to the scraping, each side of the substrate was removed by 5 μm through chemical etching. After that, the surface of the heavily doped diffusion layer 33₁ was mirror polished (FIG. 28).

After that, an N-type silicon epitaxial layer 36 having a thickness of 10 μm and a specific resistance of 10 Ωcm was formed on the mirror polished heavily doped diffusion layer 33₁ (FIG. 29). For the epitaxial growth at this point, use was made of SiHCl₃ as a silicon source, H₂ as a carrier gas, and PH₃ as a dopant gas and the growth temperature was 1150° C. The epitaxial growth rate was, on average, 1.5 am per minute. In the heavily doped diffusion layer 36, the thickness of a region of less than 2 mΩcm in specific resistance was about 50 μm.

One of the divided two substrates is illustrated and has been described, however, the same description applies to the other.

Although, in the above examples 1 and 2, the POCl₃ gas was used as the diffusion source, P₂O₅ may be applied to the substrate instead. In the above examples 2 and 3, although the heavily doped diffusion layers were formed on the top and the back of a chemically etched semiconductor substrate, they may be formed on the top and the back of a semiconductor substrate subjected to mechanical polishing or lapping using a grindstone.

The thickness of the heavily doped diffusion layer is simply set to a value that allows ohmic connection to electrode and mechanical strength of the semiconductor substrate itself to be ensured. As the heavily doped diffusion layer increases in thickness, the thermal processing time in the diffusion step increases and consequently the productivity decreases.

The non-diffusion layer underlying the heavily doped diffusion layer is required to have a thickness of 5 μm or more in order to suppress particles from the diffusion layer or travel of impurities from the back to the top of the substrate.

Conventionally, as substrates for low-voltage power devices, heavily doped substrates have been used which are doped with impurities, such as arsenic, at the time of single-crystal growth by the Czochralski method. According to each of the embodiments of the present invention, since use is made of a substrate which is lightly doped with impurities such as phosphorus or boron, the manufacturing cost can be reduced considerably in comparison with the conventional substrate. In addition, each of the embodiments can generally provide a great advantage in obtaining substrates for low-voltage power devices (mainly less than 10 Ω·cm). Of course, each of the embodiments can also be applied to the manufacture of substrates for medium-voltage power devices and substrates for high-voltage power devices (mainly more than 10 Ω·cm).

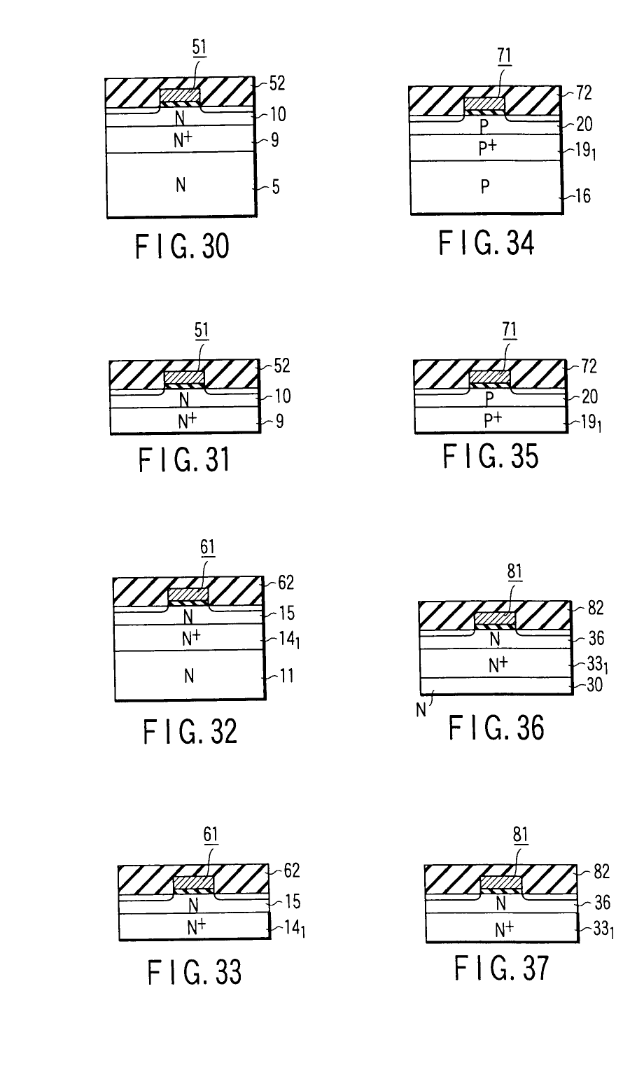

A manufacturing method of a semiconductor device, using the substrate shown in FIG. 10, will now be described with reference to FIGS. 30 and 31. FIGS. 30 and 31 are cross sectional views of a semiconductor device, for explaining steps of a manufacturing method of the semiconductor device, using the substrate shown in FIG. 10.

As shown in FIG. 30, a MOSFET 51 is formed on the substrate i.e. the N-type silicon epitaxial layer 10 by an ordinary method. Then, a passivation film 52 is formed over the substrate to cover the MOSFET 51. The N-type semiconductor substrate layer 5 is removed by, for example, grinding, at the final stage in the device manufacturing process, as shown in FIG. 31.

Similarly, a manufacturing method of a semiconductor device, using the substrate shown in FIG. 16, will now be described with reference to FIGS. 32 and 33. FIGS. 32 and 33 are cross sectional views of a semiconductor device, for explaining steps of a manufacturing method of the semiconductor device, using the substrate shown in FIG. 16.

As shown in FIG. 32, a MOSFET 61 is formed on the substrate i.e. the N-type silicon epitaxial layer 15 by an ordinary method. Then, a passivation film 62 is formed over the substrate to cover the MOSFET 61. The N-type semiconductor substrate layer 11 is removed by, for example, grinding, at the final stage in the device manufacturing process, as shown in FIG. 33.

Further, a manufacturing method of a semiconductor device, using the substrate shown in FIG. 22, will now be described with reference to FIGS. 34 and 35. FIGS. 34 and 35 are cross sectional views of a semiconductor device, for explaining steps of a manufacturing method of the semiconductor device, using the substrate shown in FIG. 22.

As shown in FIG. 34, a MOSFET 71 is formed on the substrate i.e. the a P-type silicon epitaxial layer 20 by an ordinary method. Then, a passivation film 72 is formed over the substrate to cover the MOSFET 71. The P-type semiconductor substrate layer 16 is removed by, for example, grinding, at the final stage in the device manufacturing process, as shown in FIG. 35.

Moreover, a manufacturing method of a semiconductor device, using the substrate shown in FIG. 29, will now be described with reference to FIGS. 36 and 37. FIGS. 36 and 37 are cross sectional views of a semiconductor device, for explaining steps of a manufacturing method of the semiconductor device, using the substrate shown in FIG. 29.

As shown in FIG. 36, a MOSFET 81 is formed on the substrate i.e. the N-type silicon epitaxial layer 36 by an ordinary method. Then, a passivation film 82 is formed over the substrate to cover the MOSFET 81. The N-type semiconductor substrate layer 30 is removed by, for example, grinding, at the final stage in the device manufacturing process, as shown in FIG. 37.

As a result of manufacturing a power MOSFET in accordance with the embodiments above-described, the series resistive component due to the heavily doped substrate portion could be reduced to about 70 percent of that of a conventional MOSFET and the substrate characteristics were significantly improved. Furthermore, that there is no necessity to form an excess passivation film on the back of a substrate in the epitaxial process or power device process was demonstrated. From this point of view as well, it becomes possible to further reduce the manufacturing cost.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing a semiconductor wafer comprising:
forming a heavily doped diffusion layer on a surface of a lightly doped semiconductor substrate that contains impurities at a low concentration, by carrying out a heat treatment in a gas atmosphere containing phosphorus, the heavily doped diffusion layer being higher in impurity concentration than the lightly doped semiconductor substrate; and
forming an epitaxial layer on a surface of the heavily doped diffusion layer, the epitaxial layer containing impurities at a lower concentration than the heavily doped diffusion layer.

2. The method of manufacturing a semiconductor wafer according to claim 1, wherein the method further comprises, before forming the epitaxial layer, mirror finishing the surface of the heavily doped diffusion layer on which the epitaxial layer is to be formed.

3. The method of manufacturing a semiconductor wafer according to claim 1, wherein the method further comprises, before forming the heavily doped diffusion layer, mirror finishing the surface of the lightly doped semiconductor substrate on which the heavily doped diffusion layer is to be formed.

4. The method of manufacturing a semiconductor wafer according to claim 1, wherein the heat treatment is carried out in the gas atmosphere containing at least POCl₃.

5. The method of manufacturing a semiconductor wafer according to claim 1, wherein the heat treatment in the gas atmosphere includes applying B₂O₃ powder to the surface of the lightly doped semiconductor substrate.

6. The method of manufacturing a semiconductor wafer according to claim 1, wherein the epitaxial layer is formed on the surface of the heavily doped diffusion layer, while a low impurity concentration portion of the semiconductor substrate is left.

7. The method of manufacturing a semiconductor wafer according to claim 1, wherein forming the heavily doped diffusion layer on the surface of the lightly doped semiconductor substrate includes forming heavily doped diffusion layers on a top surface and a back surface of the lightly doped semiconductor substrate;
the method further comprises removing the heavily doped diffusion layer formed on one of the top surface and the back surface of the lightly doped semiconductor substrate; and wherein
the epitaxial layer is formed on a surface of the heavily doped diffusion layer formed on the other of the top surface and the back surface of the lightly doped semiconductor substrate.

8. The method of manufacturing a semiconductor wafer according to claim 7, wherein the method further comprises, before forming the epitaxial layer, mirror finishing the surface of the heavily doped diffusion layer on which the epitaxial layer is to be formed.

9. The method of manufacturing a semiconductor wafer according to claim 7, wherein the method further comprises, before forming the heavily doped diffusion layers, mirror finishing the top or back surface of the lightly doped semiconductor substrate on which the heavily doped diffusion layer are to be formed on which the epitaxial layer is to be formed.

10. The method of manufacturing a semiconductor wafer according to claim 7, wherein the heat treatment is carried out in the gas atmosphere containing at least POCl₃.

11. The method of manufacturing a semiconductor wafer according to claim 7, wherein the heat treatment in the gas atmosphere includes applying B₂O₃ powder to the surface of the lightly doped semiconductor substrate.

12. The method of manufacturing a semiconductor wafer according to claim 7, wherein the epitaxial layer is formed on the surface of the heavily doped diffusion layer, while a low impurity concentration portion of the semiconductor substrate is left.

13. The method of manufacturing a semiconductor wafer according to claim 1, wherein forming the heavily doped diffusion layer on the surface of the lightly doped semiconductor substrate includes forming heavily doped diffusion layers on a top surface and a back surface of the lightly doped semiconductor substrate;
the method further comprises dividing the semiconductor substrate into two divided substrates by cutting the semiconductor substrate at a center in a thickness direction thereof along the top and back surfaces thereof; and wherein forming the epitaxial layer on the surface of the heavily doped diffusion layer includes forming epitaxial layers on the surfaces of the heavily doped diffusion layers formed on the top surface and the back surface of the lightly doped semiconductor substrate.

14. The method of manufacturing a semiconductor wafer according to claim 13, wherein the method further comprises, before forming the epitaxial layers, mirror finishing the surfaces of the heavily doped diffusion layers on which the epitaxial layers are to be formed.

15. The method of manufacturing a semiconductor wafer according to claim 13, wherein the method further comprises, before forming the heavily doped diffusion layers, mirror finishing the top and back surfaces of the lightly doped semiconductor substrate on which the heavily doped diffusion layers are to be formed.

16. The method of manufacturing a semiconductor wafer according to claim 13, wherein the heat treatment is carried out in the gas atmosphere containing at least POCl₃.

17. The method of manufacturing a semiconductor wafer according to claim 13, wherein the heat treatment in the gas atmosphere includes applying B₂O₃ powder to the surface of the lightly doped semiconductor substrate.

18. The method of manufacturing a semiconductor wafer according to claim 13, wherein the epitaxial layers are formed on the surfaces of the heavily doped diffusion layers, while a low impurity concentration portion of the semiconductor substrate is left.
